(19) United States
(12) Patent Application Publication
(10) Pub. No.: US 2017/0018599 A1
(43) Pub. Date: Jan. 19, 2017

(54) Pyridone Dye Composition

(71) Applicant: CLARIANT INTERNATIONAL LTD., Muttenz (CH)

(72) Inventors: Gerald ENGEL, Kelkheim (DE); Yvonne KAHLE, Klein- Winternheim (DE)

(73) Assignee: CLARIANT INTERNATIONAL LTD., Muttenz (CH)

(21) Appl. No.: 15/124,657

(22) PCT Filed: Mar. 5, 2015
(86) PCT No.: PCT/EP2015/000491

§ 371 Date: Sep. 8, 2016

(30) Foreign Application Priority Data
Mar. 8, 2014 (DE) 10 2014 003 312.0

(51) Int. Cl. H01L 27/32; G02F 1/1335; C09B 29/42; G02B 5/22; C09B 67/22; C09B 67/46

(52) U.S. Cl. CPC H01L 27/322; C09B 67/0041; C09B 67/0086; C09B 29/3626; G02B 5/223; G02F 1/133514

(57) ABSTRACT

The invention relates to a colorant composition comprising at least one compound of the formula (I) and at least one pigment, in which the compounds of the formula (I) have the following formula:

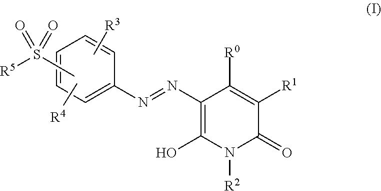

in which
R⁰ is C₁-C₆-alkyl or CF₃;
R¹ is sulfo, carboxyl, C₁-C₄-alkylenesulfo, C₁-C₄-alkylenecarboxy, CONH₂, CONH(C₁-C₄-alkyl) or CN,
R² is C₁-C₁₈-alkyl, C₂-C₁₈-alkenyl, hydroxy-C₁-C₁₈-alkyl, or —(C₁-C₆-alkylene-O—)ₘ—R where R is defined as H, C₁-C₁₆-alkyl or hydroxy-C₁-C₁₆-alkyl and m is a number from 1 to 20,
R³ is H, sulfo, carboxyl, C₁-C₆-alkyl or C₁-C₆-alkoxy,
R⁴ is H, C₁-C₆-alkyl or C₁-C₆-alkoxy,
R⁵ is OH, OM, C₁-C₆-alkyl, unsubstituted C₆-C₁₀-aryl or C₁-C₆-alkyl-, halogen- (e.g. F, Cl, Br), carboxyl- or sulfo-substituted C₆-C₁₀-aryl,
   where the compounds of the formula (I) contain at least one anionic radical from the group of sulfo and carboxyl having the countercation M⁺, where M⁺ is an alkali metal cation or an organic cation.

The colorant compositions are especially suitable for use in color filters.

The present invention relates to novel colorant compositions which are used, for example, in color filters for liquid crystal displays or in OLED displays.

Liquid crystal displays (LCDs) are widely used in television sets, PC monitors, cellphones and tablet computers for example.

The functioning of LCDs is based on the following principle: Light shines first through one polarizer, then through a liquid crystal layer and subsequently through a second polarizer. Under suitable electronic control and alignment by thin film transistors, the liquid crystals change the polarized light's direction of rotation, making it possible to control the brightness of the light emerging from the second polarizer and hence from the device.

Color filters are additionally incorporated in the arrangement between the polarizers in the case of colored LCD displays. These color filters are typically situated on the surface of a transparent substrate, usually glass, in the form of numerous uniformly arrayed pixels (picture elements) in primary colors, e.g. red, green, blue (R, G, B). A single pixel is from a few micrometers to 100 micrometers in size.

As well as the components mentioned, a liquid crystal display further comprises numerous other functional components such as thin film transistors (TFTs), alignment layers and others involved in controlling the liquid crystals and hence ultimately in picture creation.

If, then, light passes through the arrangement, the liquid crystals can be set to “bright” or “dark” (or to any stage in between)—separately for each pixel—by electronic control. The respectively assigned color filter pixels are correspondingly supplied with light and a human eye looking straight at the screen sees a corresponding colored, moving or fixed image based on R, G, B.

Different ways of arranging liquid crystals, electronic control elements and polarizers are known, for example twisted nematic (TN), super twisted nematic (STN), vertical alignment (VA) and in-plane switching (IPS).

The color filter pixels can further be arranged in different defined patterns for each primary color. Separate dots of the primary colors are arranged side by side and, illuminated from behind, produce a full color image. In addition to using the three primaries red, green and blue, it is also known to use an additional color, for example yellow, to expand the color space or to use cyan, magenta and yellow as primaries.

Color filters are likewise used in W-OLED displays. A white light is initially created in these displays from pixels of organic light emitting diodes, and subsequently split by use of color filters into individual colors, for example red, green and blue.

Color filters have to meet certain requirements: The manufacture of liquid crystal displays typically involves elevated process temperatures of 230° C. during the steps of applying the transparent liquid crystal control electrode and the alignment layer. Accordingly, the color filters used have to have high heat stability.

Further important requirements include, for example, a high contrast ratio, a high brightness for the color filter and the best possible hue.

A high contrast ratio has a positive effect on picture quality. Contrast ratio is measured by determining the intensity of light after passing through a color filter on a transparent substrate positioned between two polarizers. Contrast ratio, also called contrast value, is the ratio of the light intensities for parallel and perpendicular polarizers.

$$CR = \frac{light intensity ( parallel )}{light intensity ( perpendicular )}$$

A high level of transmission and the brightness resulting therefrom is desirable for the color filter because it means that less light has to be irradiated into the display to produce the same level of image brightness than in the case of a less bright color filter, meaning an overall energy saving.

Nowadays, color filters typically use pigmented coatings. To produce pigmented coatings, pigments are dispersed in an organic solvent in the presence of dispersing aids and then admixed with suitable binders (acrylate salts, acrylate esters, polyimides, polyvinyl alcohols, epoxides, polyesters, melamines, gelatin, caseins) and further auxiliaries to formulate a UV-curing photoresist. This photoresist is applied as a thin layer atop the carrier substrate, patterned with UV light through masks and finally developed and heat treated. Multiple repetition of these steps for the individual primary colors creates the color filter in the form of a pixel pattern.

Dyes are also being increasingly used in color filters in order that contrast value, brightness, hue and transmission may each be optimized to the stipulated purpose. However, commercially available dyes in particular lack fastness, in particular thermal stability, and have inadequate coloristic properties.

Patent JP S62-180302 (1986) describes the use for color filters of various acid dyes in the form of the free acid. However, the azo compounds recited therein exhibit insufficient stability to heat. Nor is working with free acids in keeping with best workplace health and safety practice.

US2012/205599A1 describes green color filters which, as well as a green or cyan pigment, also comprise a yellow dye as coloring component. Pyridone dyes are one possible kind of dye, but these are free of acid groups.

Color filter colorants have to meet ever increasing demands. Even commercially available products do not always meet all technical requirements. More particularly, there is a need for improvement with regard to heat stability, contrast values and brightness on the part of the colorants used, without adverse effect on chroma and hue. A desirable feature in the case of dyes is a good solubility of the colorants in the use system. A further object was that of providing greenish yellow dyes having good heat stability for color filter applications.

It has now been found that, surprisingly, novel colorant compositions composed of dyes of the formula (I) and pigments are of good suitability for use in color filters.

In compositions comprising organic pigments, the compounds of the formula (I) improve the dispersibility of the pigments and allow color hue adjustment. As a result, they lead to advantageous performance properties such as reduced viscosity in dispersions, and increased brilliance and high contrast value in the color filter.

The invention provides colorant compositions comprising at least one compound of the formula (I) and at least one pigment, in which the compounds of the formula (I) have the following formula:

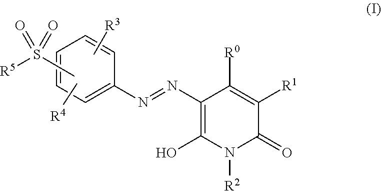

in which
R⁰ is C₁-C₆-alkyl or CF₃;
R¹ is sulfo, carboxyl, C₁-C₄-alkylenesulfo, C₁-C₄-alkylenecarboxy, CONH₂, CONH(C₁-C₄-alkyl) or CN,
R² is C₁-C₁₈-alkyl, C₂-C₁₈-alkenyl, hydroxy-C₁-C₁₈-alkyl, or —(C₁-C₆-alkylene-O—)ₘ—R where R is defined as H, C₁-C₁₆-alkyl or hydroxy-C₁-C₁₆-alkyl and m is a number from 1 to 20,
R³ is H, sulfo, carboxyl, C₁-C₆-alkyl or C₁-C₆-alkoxy,
R⁴ is H, C₁-C₆-alkyl or C₁-C₆-alkoxy,
R⁵ is OH, OM, C₁-C₆-alkyl, unsubstituted C₆-C₁₀-aryl or C₁-C₆-alkyl-, halogen- (e.g. F, Cl, Br), carboxyl- or sulfo-substituted C₆-C₁₀-aryl,
   where the compounds of the formula (I) contain at least one anionic radical from the group of sulfo and carboxyl, preferably sulfo, with the countercation M⁺, where M⁺ is an alkali metal cation, such as Li⁺, Na⁺ or K⁺, or preferably an organic cation, especially an organic ammonium cation or an organic phosphonium cation.

It is also possible that the countercation M⁺ is a mixture of the aforementioned cations.

The alkylene groups and the alkyl groups in the alkyl and alkoxy radicals are branched or linear. Examples of alkyl groups are methyl, ethyl, propyl, isopropyl, butyl, preferably n-butyl and isobutyl, pentyl, preferably n-pentyl and isopentyl, hexyl, octyl, ethylhexyl.

The C₁-C₆-alkylene-O— groups in the —(C₁-C₆-alkylene-O—)ₘ—R radical may be the same or different when m is greater than 1.

Preferred R⁰ radicals are defined as C₁-C₂-alkyl, most preferably methyl.

Preferred R¹ radicals are defined as C₁-C₂-alkylenesulfo, CONH(C₁-C₂-alkyl) or CONH₂, more preferably C₁-C₂-alkylenesulfo, CONH(C₁-C₂)alkyl or CONH₂, most preferably CH₂-sulfo or CONH₂.

Preferred R² radicals are defined as C₁-C₈-alkyl, hydroxy-C₁-C₈-alkyl or —(C₁-C₄-alkylene-O—)ₘ—R where R is defined as H or C₁-C₁₀-alkyl and m is a number from 1 to 15, especially ethyl, hydroxyethyl or —(C₁-C₃-alkylene-O—)ₘ—R where R is defined as H or C₁-C₈-alkyl and m is a number from 1 to 15, most preferably ethyl or —(C₂-C₃-alkylene-O—)ₘ—R where R is defined as H or methyl and m is a number from 1 to 12.

Preferred R³ radicals are defined as H, sulfo, C₁-C₄-alkyl or C₁-C₄-alkoxy, especially H, methyl, methoxy or sulfo, most preferably H or methyl.

Preferred R⁴ radicals are defined as H, C₁-C₄-alkyl or C₁-C₄-alkoxy, especially H, methyl or methoxy, most preferably H.

Preferred R⁵ radicals are defined as OH, O⁻M⁺, C₁-C₄-alkyl, phenyl substituted by C₁-C₂-alkyl, halogen, e.g. F, Cl, Br, or sulfo, or unsubstituted phenyl, especially OH, O⁻M⁺, C₁-C₂-alkyl, a C₁-C₂-alkyl-, chlorine- or sulfo-substituted phenyl or an unsubstituted phenyl, most preferably OH, O⁻M⁺, methyl, tolyl or phenyl, where M⁺ is an alkali metal cation, a primary, secondary, tertiary or quaternary ammonium ion or a phosphonium ion.

In preferred compounds of the formula (I):
R⁰ is C₁-C₂-alkyl, especially methyl,
R¹ is C₁-C₄-alkylenesulfo, CONH(C₁-C₂-alkyl) or CONH₂, especially C₁-C₂-alkylenesulfo, CONH(C₁-C₂-alkyl) or CONH₂,
R² is C₁-C₈-alkyl, hydroxy-C₁-C₈-alkyl or —(C₁-C₄-alkylene-O—)ₘ—R where R is defined as H or C₁-C₁₀-alkyl and m is a number from 1 to 15,
R³ is H, sulfo, C₁-C₄-alkyl or C₁-C₄-alkoxy,
R⁴ is H, C₁-C₄-alkyl or C₁-C₄-alkoxy,
R⁵ is OH, O⁻M⁺, C₁-C₄-alkyl, phenyl substituted by C₁-C₂-alkyl, halogen, e.g. F, Cl, Br, or sulfo, or unsubstituted phenyl,
   where the compounds of the formula (I) contain at least one sulfo group, preferably 1 or 2 sulfo groups, and the countercation M⁺ is as defined above.

In more preferred compounds of the formula (I):
R⁰ is methyl,
R¹ is C₁-C₂-alkylenesulfo, CONH(C₁-C₂-alkyl) or CONH₂,
R² is ethyl, hydroxyethyl or —(C₁-C₃-alkylene-O—)ₘ—R where R is defined as H or C₁-C₈-alkyl and m is a number from 1 to 15,
R³ is H, methyl, methoxy or sulfo,
R⁴ is H, methyl or methoxy,
R⁵ is OH, O⁻M⁺, C₁-C₂-alkyl, a C₁-C₂-alkyl-, chlorine- or sulfo-substituted phenyl or unsubstituted phenyl,
   where the compounds of the formula (I) contain 1 or 2 sulfo groups and the counter-cation M⁺ is as defined above.

In particularly preferred compounds of the formula (I):
R⁰ is methyl,
R¹ is CH₂-sulfo or CONH₂,
R² is ethyl or —(C₂-C₃-alkylene-O—)ₘ—R where R is defined as H or methyl and m is a number from 1 to 12,
R³ is H or methyl,
R⁴ is H,
R⁵ is OH, O⁻M⁺, methyl, tolyl or phenyl,
   where the compounds of the formula (I) contain 1 or 2 sulfo groups, especially 1 sulfo group, and the countercation M⁺ is as defined above.

An example of a particularly preferred compound is (IIa):

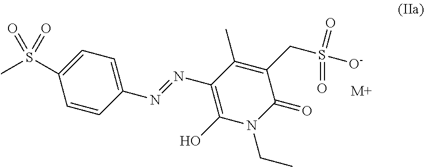

In all the above-described inventive compounds of the formulae (I) and (IIa), the countercation M⁺ is preferably an organic cation from the group of the imidazolium cations, alkylguanidinium cations, phosphonium cations, primary, secondary, tertiary or quaternary ammonium ions, benzotriazolyl cations and pyridinium cations.

The imidazolium cations preferably have the formula (C1):

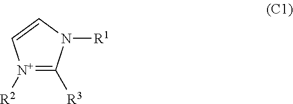

in which
R¹ is C₁-C₁₈-alkyl, hydroxy-C₁-C₁₈-alkyl, C₂-C₁₈-alkenyl, —(C₁-C₆-alkylene-O—)ₘ—R where R is defined as H, C₁-C₁₆-alkyl or hydroxy-C₁-C₁₆-alkyl and m is a number from 1 to 20, C₆-C₁₀-aryl or C₆-C₁₀-aryl substituted by 1, 2 or 3 C₁-C₄-alkyl radicals,
R² is C₁-C₁₈-alkyl, hydroxy-C₁-C₁₈-alkyl, C₂-C₁₈-alkenyl, —(C₁-C₆-alkylene-O—)ₘ—R where R is defined as H, C₁-C₁₆-alkyl or hydroxy-C₁-C₁₆-alkyl and m is a number from 1 to 20, C₆-C₁₀-aryl or C₆-C₁₀-aryl substituted by 1, 2 or 3 C₁-C₄-alkyl radicals,
R³ is H or methyl.

Particular preference is given to imidazolium cations of the formula (C1) in which R¹ and R² are the same or different and are each C₄-C₁₂-alkyl, —(C₁-C₃-alkylene-O—)ₘ—R where R is defined as H, C₁-C₁₂-alkyl or hydroxy-C₁-C₁₂-alkyl and m is a number from 1 to 3, phenyl or di(isopropyl)phenyl, and R³ is hydrogen or methyl.

Very particular preference is given to imidazolium cations of the formula (C1) in which R¹ and R² are the same or different and are each C₆-C₁₂-alkyl, —(C₂-C₃-alkylene-O—)ₘ—R where R is defined as C₄-C₁₂-alkyl and m is the number 1; or phenyl or di(isopropyl)phenyl, and R³ is hydrogen or methyl.

The alkylguanidinium cations preferably have the formula (C2):

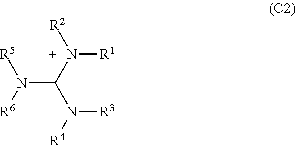

in which
R¹, R², R³ and R⁴ are the same or different and are each C₁-C₄-alkyl, preferably methyl or ethyl, and
R⁵ and R⁶ are the same or different and are each C₁-C₁₈-alkyl, hydroxy-C₁-C₁₈-alkyl, C₂-C₁₈-alkenyl, C₆-C₁₀-aryl, —(C₁-C₆-alkylene-O—)ₘ—R where R is defined as H, C₁-C₁₆-alkyl or hydroxy-C₁-C₁₆-alkyl and m is a number from 1 to 20; preferably, R⁵ and R⁶ are each C₆-C₁₂-alkyl or phenyl.

The phosphonium cations preferably have the formula (C3):

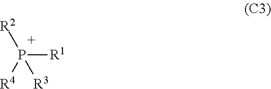

in which
R¹ is C₁-C₆-alkyl or hydroxy-C₁-C₆-alkyl,
R² is C₁-C₆-alkyl, C₂-C₆-alkenyl, hydroxy-C₁-C₆-alkyl or C₆-C₁₀-aryl,
R³ is C₁-C₂₀-alkyl, C₂-C₂₀-alkenyl, hydroxy-C₁-C₂₀-alkyl, C₆-C₁₀-aryl, —(C₁-C₆-alkylene-O—)ₘ—R where R is defined as H, C₁-C₁₆-alkyl or hydroxy-C₁-C₁₆-alkyl and m is a number from 1 to 20,
R⁴ is C₁-C₂₀-alkyl, C₂-C₂₀-alkenyl, C₆-C₁₀-aryl, hydroxy-C₁-C₂₀-alkyl, —(C₁-C₆-alkylene-O—)ₘ—R where R is defined as H, C₁-C₁₆-alkyl or hydroxy-C₁-C₁₆-alkyl and m is a number from 1 to 20.

Particular preference is given to phosphonium cations of the formula (C3) in which R¹, R² and R³ are the same or different and are each C₁-C₄-alkyl or phenyl, and R⁴ is C₆-C₁₈-alkyl or phenyl.

The organic ammonium cations are primary, secondary, tertiary or quaternary ammonium cations and preferably have the formula (C4):

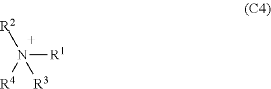

in which
R¹, R², R³ and R⁴ are the same or different and are each hydrogen, (C₁-C₃₀)-alkyl, (C₂-C₃₀)-alkenyl, hydroxy (C₁-C₃₀)-alkyl, C₁-C₄-alkylenephenyl, (C₆-C₁₀)-aryl, C₁-C₆-alkylene-OCOR⁵ where R⁵ is C₆-C₂₀-alkyl or C₆-C₂₀-alkenyl; —(C₁-C₆-alkylene-O—)ₘ—R where R is defined as H, C₁-C₁₆-alkyl or hydroxy-C₁-C₁₆-alkyl and m is a number from 1 to 20;
   with the proviso that the sum total of the carbon atoms in the R¹ to R⁴ radicals is at least 6, preferably at least 8, especially at least 12, more preferably at least 16.

In more preferred compounds of the formula (C4):
R¹ is H, C₁-C₄-alkyl, hydroxy-C₂-C₄-alkyl,
R² is H, C₁-C₃₀-alkyl, hydroxy-C₂-C₄-alkyl, benzyl, C₄-C₃₀-alkenyl, phenyl or C₁-C₄-alkylene-OCOR⁵ where R⁵ is C₈-C₁₈-alkyl or C₈-C₁₈-alkenyl,
R³ is H, C₁-C₃₀-alkyl, C₄-C₃₀-alkenyl, benzyl, phenyl or C₁-C₄-alkylene-OCOR⁵ where R⁵ is C₈-C₁₈-alkyl or C₈-C₁₈-alkenyl,
R⁴ is C₄-C₃₀-alkyl, C₄-C₃₀-alkenyl, benzyl or phenyl, with the proviso defined above.

In particularly preferred compounds of the formula (C4):
R¹ is H, C₁-C₂-alkyl, hydroxyethyl,
R² is H, C₁-C₂₀-alkyl, hydroxyethyl, benzyl, phenyl or CH₂—OCOR⁵ where R⁵ is C₈-C₁₈-alkyl or C₈-C₁₈-alkenyl,
R³ is H, C₁-C₂₀-alkyl, C₆-C₂₀-alkenyl, benzyl, phenyl or CH₂—OCOR⁵ where R⁵ is C₈-C₁₈-alkyl or C₈-C₁₈-alkenyl,
R⁴ is C₆-C₂₀-alkyl, C₆-C₂₀-alkenyl, benzyl or phenyl, with the proviso defined above.

Examples of ammonium cations of the formula (C4) are:

stearylammonium, oleylammonium, ethylhexylammonium, coconut fat ammonium, 3-isotridecyl ether propylammonium, didecylammonium, diisotridecylammonium, dimethyldecylammonium, Jeffamine® M600 ammonium, triethylammonium, didecyldimethylammonium, distearyldimethylammonium, trioctylmethylammonium, cocoalkyldimethylbenzylammonium, bis(N,N-hydroxyethyl)dodecylmethylammonium, methyltrioctylammonium, N,N-bisstearoylethyl-N,N-dimethylammonium.

The benzotriazolium cations preferably have the formula (C5):

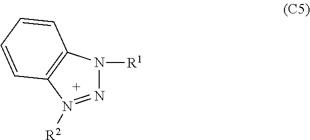

in which
R¹ and R² are the same or different and are each C₁-C₁₂-alkyl, hydroxy-(C₁-C₁₂)alkyl, —(C₁-C₆-alkylene-O—)ₘ—R where R is defined as H, C₁-C₁₆-alkyl or hydroxy-C₁-C₁₆-alkyl and m is a number from 1 to 20, or C₆-C₁₀-aryl, preferably C₂-C₈-alkyl or phenyl.

The pyridinium cations preferably have the formula (C6):

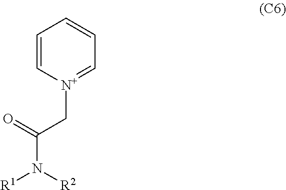

in which
R¹ and R² are the same or different and are each C₁-C₁₈-alkyl, hydroxy(C₁-C₁₈)alkyl, —(C₁-C₆-alkylene-O—)ₘ—R where R is defined as H, C₁-C₁₆-alkyl or hydroxy-C₁-C₁₆-alkyl and m is a number from 1 to 20, or C₆-C₁₀-aryl, preferably C₄-C₁₂-alkyl, or phenyl.

Useful pigments include inorganic or organic pigments, preferably organic pigments.

For the compositions of the invention, it is possible to use the following organic pigments for example: anthraquinone pigments, laked or unlaked azo pigments, anthanthrone pigments, benzimidazolone pigments, quinacridone pigments, quinophthalone pigments, diketopyrrolopyrrole pigments, dioxazine pigments, disazo condensation pigments, isoindolinone pigments, isoindoline pigments, metal complex pigments, perinone pigments, perylene pigments, phthalocyanine pigments and triarylcarbonium pigments.

Preferred yellow pigments are C.I. Pigment Yellow 138, 139, 150, 151, 155, 180, 213 and 214. Particular preference is given to C.I. Pigment Yellow 138, 139 or 150.

Preferred red pigments are C.I. Pigment Red 122, 149, 166, 168, 177, 242, 254, 264; particular preference is given to PR 254, PR 264, PR 242 or PR 177.

Preference is further given to C.I. Pigment Orange 34, 36, 38, 43, 62, 64, 68, 71, 72, 73, 74, and 81.

Preferred green pigments are C.I. Pigment Green 7, 36 and 58.

In the blue and violet range, preference is given to C.I. Pigment Blue 15:6, 15:3, 15:2, 15:1 and 15, Pigment Blue 80 and C.I. Pigment Violet 19 and 23. Particular preference is given to Pigment Blue 15:6 and Pigment Blue 80.

The mixing ratios of compound of the formula (I) to pigment, preferably organic pigment, may in principle be 1:99 to 99:1 parts by weight. In order to achieve particular coloristic properties, the ratio between compound of the formula (I) and pigment may vary within wide limits, for example from 5:95 to 95:5, preferably 10:90 to 90:10, more preferably from 20:80 to 80:20, even more preferably 30:70 to 70:30, especially 40:60 to 60:40, parts by weight.

In the case that the compound of the formula (I) is to be used primarily as a dispersing improver for the pigment, smaller amounts may also suffice, for example 1% to 20% by weight, preferably 2% to 10% by weight, of compound of the formula (I), based on the total weight of the colorant composition.

The compounds of the formula (I) can be prepared by diazotization of amines of the formula (A), preferably at a temperature of 0 to 10° C., and azo coupling with one equivalent of the pyridone coupling component of the formula (P), preferably at a temperature of 0 to 40° C.,

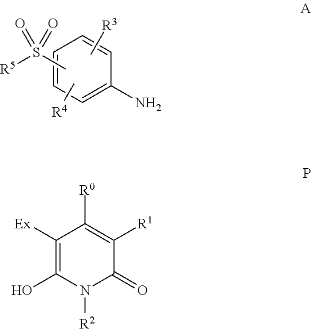

in which
R⁰ to R⁵ are each as defined above and
Ex is a leaving group, e.g. H or carbamoyl,
and optionally subsequent exchange of the cation obtained in the synthesis, e.g. H⁺ or Na⁺, for the cation M⁺.

The compounds of the formulae (A) and (P) are known to those skilled in the art from the literature.

In the diazotization, the amine in question is appropriately cooled down to 0 to 10° C., preferably to 0 to 5° C., and diazotized by addition of nitrosylsulfuric acid or sodium nitrite in an acidic medium, for example between pH 0 and 5. Subsequently, the diazotized amine is allowed to react with the coupling component P, preferably in aqueous solution. In general, the coupling reaction is conducted at temperatures of 0 to 40° C. The pH is typically between 4 and 9. It can also be adjusted to the desired range through use of a suitable buffer.

The dyes formed can be isolated from the reaction medium by salt precipitation with an alkali metal salt, filtration and drying, if necessary under reduced pressure and at elevated temperature.

Depending on the reaction and workup conditions, the dyes of the formula (I) can be obtained as the free acid, as a salt or as a mixed salt containing, for example, one or more cations from the alkali metal cations, for example sodium ion, or the ammonium ions or phosphonium ions. If desired, the dye salts of the formula (I) can be purified further, for example by diafiltration through a semipermeable membrane or recrystallization, which removes unwanted by-products and inorganic salts from the crude product.

The salts with the organic counterions M⁺ can be obtained from the dye alkali metal salts, for example, by mixing an aqueous solution of the dye alkali metal salt at elevated temperature, e.g. 40 to 95° C., with an aqueous solution of the counterion halide salt and extracting the newly formed dye salt into an organic solvent of preferably zero or low water solubility, for example methoxypropyl acetate. The dye salts of the formula (I) with the organic counterions M⁺ can be isolated from the organic phase after the solvent has been removed, optionally in conjunction with a purification step.

The parent compounds for the formulae (C1) to (C6) are common knowledge to those skilled in the art. For example, imidazolium halides (C1) which find use as ionic liquids and also as phase transfer catalysts can be prepared according to U.S. Pat. No. 5,132,423.

Benzotriazolium halides (C5) can be prepared, for example, according to Kuhn et al., Chem. Ber. 1940, 1109-1113.

Pyridinium halides (C6) can be obtained by a procedure known to those skilled in the art from pyridine and methyl chloroacetate and subsequent reaction with the appropriate amine.

The inventive colorant compositions can be used to color high molecular weight organic materials of natural or synthetic origin, for example plastics, resins, coating materials, especially metallic coating materials, paints, electrophotographic toners and developers, electret materials, and inks, inkjet inks, printing inks and seed.

High molecular weight organic materials which can be colored with the colorant compositions of the invention are, for example, cellulose compounds, for example cellulose ethers and esters, such as ethyl cellulose, nitrocellulose, cellulose acetates or cellulose butyrates, natural binders, for example fatty acids, fatty oils, resins and conversion products thereof, or synthetic resins such as polycondensates, polyadducts, polymers and copolymers, for example amino resins, especially urea- and melamine-formaldehyde resins, alkyd resins, acrylic resins, phenolic resins such as novolaks or resols, urea resins, polyvinyls such as polyvinyl alcohols, polyvinyl acetals, polyvinyl acetates or polyvinyl ethers, polycarbonates, polyolefins such as polystyrene, polyvinyl chloride, polyethylene or polypropylene, styrene-butadiene copolymers, poly(meth)acrylates and copolymers thereof, such as polyacrylic esters, styrene-acrylates, or polyacrylonitriles, polyamides, polyesters, polyurethanes, polysulfones, coumarone-indene and hydrocarbon resins, epoxy resins, phenol-epoxy resins, unsaturated synthetic resins (polyesters, acrylates) with different curing mechanisms, waxes, aldehyde and ketone resins, vulcanized and unvulcanized rubber and derivatives and latices thereof, casein, silicones and silicone resins; individually or in mixtures. It does not matter here whether the high molecular weight organic compounds mentioned are present in the form of plastic masses or melts or in the form of spinning solutions, dispersions, coating materials, paints or printing inks.

The invention therefore likewise provides a high molecular weight organic medium comprising a coloristically effective amount of a colorant composition of the invention.

Based on the high molecular weight organic material to be colored, the colorant compositions of the invention are usually used in an amount of 0.01% to 45% by weight, preferably 0.1% to 40% by weight.

Preference is given to the use of the colorant compositions for color filters and the bulk coloring of polymers.

Particular preference is given to use as a colorant for color filters, suitable both for additive and subtractive color creation, for example in electrooptical systems such as LCDs (liquid crystal displays), OLED displays, charge coupled devices, plasma displays or electroluminescent displays, which may in turn be active (twisted nematic) or passive (supertwisted nematic) ferroelectric displays or light-emitting diodes, and also as colorants for electronic inks (“e-inks”) or electronic paper (“e-paper”).

The inventive colorant compositions composed of pigment and dye of the formula (I) may also take the form of a millbase or of a binder-containing colorant dispersion (photoresist).

The present invention therefore also provides a millbase comprising 0.01% to 45% by weight, preferably 2% to 20% by weight, especially 7% to 17% by weight, of the colorant composition composed of compounds of the formula (I) and pigment, dispersed in an organic solvent.

Examples of useful organic solvents include:

ethyl lactate, benzyl alcohol, 1,2,3-trichloropropane, 1,3-butanediol, 1,3-butylene glycol, 1,3-butylene glycol diacetate, 1,4-dioxane, 2-heptanone, 2-methyl-1,3-propanediol, 3,5,5-trimethyl-2-cyclohexen-1-one, 3,3,5-trimethylcyclohexanone, 3-ethoxyethylpropionate, 3-methyl-1,3-butanediol, 3-methoxy-3-methyl-1-butanol, 3-methoxy-3-methylbutyl acetate, 3-methoxybutanol, 3-methoxybutyl acetate, 4-heptanone, m-xylene, m-diethylbenzene, m-dichlorobenzene, N,N-dimethylacetamide, N,N-dimethylformamide, n-butyl alcohol, n-butylbenzene, n-propyl acetate, o-xylene, o-chlorotoluene, o-diethylbenzene, o-dichlorobenzene, p-chlorotoluene, p-diethylbenzene, sec-butylbenzene, tert-butylbenzene, gamma-butyrolactone, isobutyl alcohol, isophorone, ethylene glycol diethyl ether, ethylene glycol dibutyl ether, ethylene glycol monoisopropyl ether, ethylene glycol monoethyl ether, ethylene glycol monoethyl ether acetate, ethylene glycol mono-tert-butyl ether, ethylene glycol monobutyl ether, ethylene glycol monobutyl ether acetate, ethylene glycol monopropyl ether, ethylene glycol monohexyl ether, ethylene glycol monomethyl ether, ethylene glycol monomethyl ether acetates, diisobutylketone, diethylene glycol diethyl ether, diethylene glycol dimethyl ether, diethylene glycol monoisopropyl ether, diethylene glycol monoethyl ether acetate, diethylene glycol monobutyl ether, diethylene glycol monobutyl ether acetate, diethylene glycol monomethyl ether, cyclohexanol, cyclohexanol acetate, cyclohexanone, dipropylene glycol methyl ether, dipropylene glycol methyl ether acetate, dipropylene glycol monoethyl ether, dipropylene glycol monobutyl ether, dipropylene glycol monopropyl ether, dipropylene glycol monomethyl ether, diacetone alcohol, triacetylglycerol, tripropylene glycol monobutyl ether, tripropylene glycol monomethyl ether, propylene glycol diacetate, propylene glycol phenyl ether, propylene glycol monoethyl ether, propylene glycol monoethyl ether acetates, propylene glycol monobutyl ether, propylene glycol monopropyl ether, propylene glycol monomethyl ether, propylene glycol monomethyl ether acetate, propylene glycol monomethyl ether propionates, benzyl alcohol, methyl isobutyl ketone, methylcyclohexanol, n-amyl acetate, n-butyl acetate, isoamyl acetate, isobutyl acetate, propyl acetates, dibasic ester (DBE).

Of particular advantage are ethyl lactate, propylene glycol monomethyl ether acetate (methoxypropyl acetate), propylene glycol monoethyl ether acetate, ethylene glycol monomethyl ether acetate, ketones such as cyclohexanone or alcohols such as n-butanol or benzyl alcohol.

The organic solvents can be used alone or mixed with one another.

Depending on the application, the colorant compositions of the invention can be combined with customary auxiliaries or additives to give a colorant composition, examples being surfactants, dispersants, rheology control additives, fillers, regulators, resins, waxes, defoamers, dust suppressants, extenders, antistats, charge controllers, preservatives, drying retardants, wetting agents, antioxidants, UV absorbers, light stabilizers and binders, for example the binders for the system in which the composition of the invention is to be used. If present, the auxiliaries and additives are used preferably in an amount of 0.01% to 15% by weight, especially 0.5% to 10% by weight, based on the total weight of the colorant composition.

For color filters in particular, the colorant composition of the invention may also comprise, for example, surfactants, dispersants, resins and waxes.

The millbase of the invention may especially comprise dispersing aids.

Useful dispersing assistants include commonly known compounds, for example polymeric dispersing assistants. These are typically polymers or copolymers based on polyesters, polyacrylates, polyurethanes and polyamides. Wetting agents may further be used, examples being anionic or nonionic wetting agents. The recited wetting agents and dispersing assistants can be used individually or in combination. They are appropriately used in an amount of 2% to 90% by weight, preferably 10% to 50% by weight, based on the total weight of the colorant composition.

To produce the millbase, the colorant composition of the invention is subjected to a dispersion, for which customary dispersing units may be used.

When the colorant composition of the invention is used in the form of a dispersed colorant in a millbase, a small primary particle size for the pigment is advantageously first set in a suitable manner. Particularly suitable primary particle sizes are less than 60 nm and preferably less than 40 nm in the d₅₀. It is similarly advantageous to set a narrow particle size distribution.

The particle size distribution after comminution preferably approximates a Gaussian distribution in which the standard deviation sigma is preferably less than 30 nm and more preferably less than 20 nm. The standard deviations are generally between 5 and 30 nm, preferably between 6 and 25 nm and particularly between 7 and 20 nm.

The standard deviation sigma (σ) corresponds to the positive square root of the variance. The variance v is the sum total of the squared deviations from the mean, divided by the number of samples minus 1. It is further advantageous for the d₉₅ of the comminuted particles to be not more than 70 nm. The length to width ratio of the comminuted particles is preferably between 2:1 and 1:1.

One way to achieve the fine state of subdivision is salt kneading with a crystalline inorganic salt in the presence of an organic solvent. Useful crystalline inorganic salts include, for example, aluminum sulfate, sodium sulfate, calcium chloride, potassium chloride or sodium chloride, preferably sodium sulfate, sodium chloride and potassium chloride. Useful organic solvents include, for example, ketones, esters, amides, sulfones, sulfoxides, nitro compounds, mono-, bis- or tris-hydroxy-C₂-C₁₂-alkanes which may be substituted by C₁-C₈-alkyl and one or more hydroxyl groups. Particular preference is given to water-miscible high-boiling organic solvents based on monomeric, oligomeric and polymeric C₂-C₃-alkylene glycols, e.g., diethylene glycol, diethylene glycol monomethyl ether, diethylene glycol monoethyl ether, triethylene glycol, triethylene glycol monomethyl ether, triethylene glycol monoethyl ether, dipropylene glycol, dipropylene glycol monomethyl ether, dipropylene glycol monoethyl ether, propylene glycol monomethyl ether, propylene glycol monoethyl ether and liquid polyethylene glycols and polypropylene glycols, n-methylpyrrolidone and also triacetin, dimethylformamide, dimethylacetamide, ethyl methyl ketone, cyclohexanone, diacetone alcohol, butyl acetate, nitromethane, dimethyl sulfoxide and sulfolane.

The weight ratio between the organic salt and the pigment used or the colorant composition is preferably (2 to 10):1, especially (3 to 7):1. The weight ratio between the organic solvent and the inorganic salt is preferably (1 mL:10 g) to (2 mL:7 g). The weight ratio between the organic solvent and the sum total of inorganic salt and the colorant composition of the invention or the pigment used is preferably (1 mL:2 g) to (1 mL:10 g).

The temperature during the kneading may be between 40 and 140° C., preferably 60 to 120° C. The kneading time is appropriately 4 h to 32 h, preferably 8 h to 20 h.

After the salt kneading, the inorganic salt and the organic solvent are appropriately removed by washing with water, and the comminuted colorants thus obtained are dried by customary methods.

The material obtained following the conversion to a fine state of subdivision may optionally be subjected in the form of a suspension, filter cake or dry material to a solvent aftertreatment (finish treatment) in order to obtain a more homogenous particle shape without noticeable increase in the particle size. Preference is given to using steam-volatile solvents such as alcohols and aromatic solvents, more preferably branched or unbranched C₁-C₆ alcohols, toluene, xylene, chlorobenzene, dichlorobenzene, nitrotoluene or nitrobenzene usually under elevated temperature, for example at up to 200° C., and optionally under elevated pressure.

The invention further provides a binder-containing colorant dispersion comprising 0.01% to 40% by weight, preferably 0.1% to 30% by weight, especially 1% to 20% by weight, of the colorant composition of the invention, dispersed in at least one organic solvent, at least one polymeric binder and optionally further auxiliaries.

The binder-containing colorant dispersion is appropriately produced by mixing the above-described colorant dispersion (millbase) with the other components mentioned.

Useful polymeric binders include, for example, acrylate salts, acrylate esters, polyimides, polyvinyl alcohols, epoxides, polyesters, melamines, gelatin, caseins and polymerizable ethylenically unsaturated monomers and oligomers, preferably those which crosslink either thermally or under the effect of UV light and free-radical initiators. The amount of polymeric binders is advantageously from 5 to 90 wt % and preferably from 20 to 70 wt % based on the total amount of all nonvolatile constituents of the colorant dispersion. Nonvolatile constituents are the compounds of formula (I), the pigments, the polymeric binders and the further auxiliaries. Volatile constituents are the organic solvents which are volatile under the baking temperatures used.

Useful further auxiliaries include, for example, crosslinkers and free-radical initiators, leveling aids, defoamers and devolatilizers. They are appropriately present in an amount of 0% to 10% by weight, preferably of 0% to 5% by weight, based on the total amount of the colorant dispersion.

In the case that further auxiliaries are used, an appropriate lower limit is 0.01% by weight, preferably 0.1% by weight, based on the total amount of the colorant dispersion.

Useful organic solvents include the solvents mentioned above for the millbase. They are appropriately present in an amount of 10% to 90% by weight, preferably of 20% to 80% by weight, based on the total amount of the colorant dispersion.

The yellow hues of the compounds and colorant compositions of the invention are of very particular suitability for the red-green-blue (R,G,B) color filter color set. Separate dots of these three colors are arranged side by side and, illuminated from behind, produce a full color image. There additionally exist color filter systems which work with the four primaries red-green-blue and yellow (R,G,B,Y), for which the colorants of the invention are likewise of good suitability.

The present invention also provides a process for producing the colorant compositions of the invention from compounds of the formula (I) and pigment, which comprises combining the compounds of the formula (I) and the organic pigments with one another. Appropriately, optionally after reducing the primary particle size, combination is effected in one dispersion step, or by mixing a solution or dispersion of compounds of the formula (I) with a dispersion of the pigment.

The respective components can be used in dry form, for example in granular or pulverulent form, or in moist form, for example as a presscake.

Preference is given to combination during a reduction in the primary particle size. This serves to achieve smaller particle sizes, narrower particle size distributions and, as a result, further optimization of the performance properties, especially for color filters. The primary particle size can be reduced by a wet or dry grinding operation, but preferably by a salt kneading operation with a crystalline inorganic salt in the presence of an organic solvent, as described above.

The invention further provides for the use of the colorant compositions, including in the form of the millbase described or in binder-containing colorant dispersions, in color filters.

The use concentration of the colorant composition of the invention in the color filter film applied may be between 5% and 95% by weight, preferably between 10% and 70% by weight, most preferably between 15% and 50% by weight, based on the total weight of the color filter film.

The invention also provides a color filter comprising a coloristically effective amount of the colorant composition of the invention.

In the examples which follow, percentages are percentages by weight and parts are parts by weight, unless stated otherwise.

### EXAMPLES

### Preparation of the Acid Azo Dye (I a)

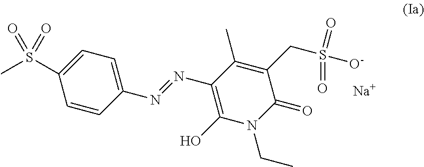 [SMILES: CCn1c(O)c(/N=N/c2ccc(S(C)(=O)=O)cc2)c(C)c(CS(=O)(=O)[O-])c1=O ; [Na+]]

A suspension consisting of 17.1 g of 4-aminophenyl methyl sulfone (0.10 mol) in 100 mL of water and 22 mL of conc. hydrochloric acid (37% by weight) is diazotized at 0-5° C. with 17.3 g of sodium nitrite solution (40% by weight; 0.1 mol of NaNO₃). The resultant diazonium salt is added in portions at 0 to 5° C. to a suspension consisting of 24.6 g (0.1 mol) of the compound of the following formula

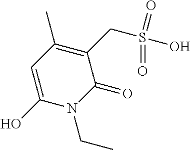 [SMILES: CCn1c(O)cc(C)c(CS(=O)(=O)O)c1=O]

in 9 mL of 30% sodium hydroxide solution and 50 mL of water. By adding 15% by weight sodium carbonate solution, the pH is kept at 7 to 9. The volume of the dye suspension is made up to about 700 mL with water, then the mixture is heated to 90° C. for 30 min. After cooling, the solids are filtered off with suction, washed with water and dried under reduced pressure. This gives 40.2 g of a yellow dye powder of the formula (I a).

### Preparation of the Hexaalkylguanidinium Chloride (C2a)

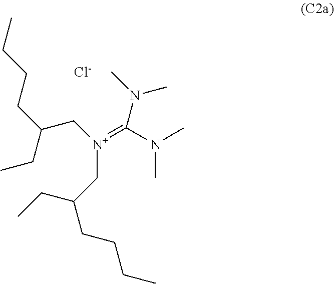 [SMILES: CCCCC(CC)C[N+](CC(CC)CCCC)=C(N(C)C)N(C)C ; [Cl-]]

To a solution of 15.5 mL (0.13 mol) of tetramethylurea in 60 mL of toluene are added dropwise, at 60-65° C., 13 mL (0.13 mol) of phosphoryl chloride. After stirring for two hours, the mixture is cooled and, at 0-5° C., a mixture of 18 mL of triethylamine and 40 mL (0.14 mol) of bis(2-ethylhexyl)amine in 30 mL of toluene is added dropwise. Subsequently, the temperature is allowed to rise to about 20° C., and stirring is continued overnight. Then the pale yellow mixture is admixed with 54 mL of NaOH (30% by weight) while cooling. The mixture is stirred together with 150 mL of NaCl solution. The toluene phase is separated off and dried with magnesium sulfate, and the solvent is removed under reduced pressure. This gives 47 g of a pale beige, waxy solid.

### Preparation of the Hexaalkylguanidinium Dye Salt (I b)

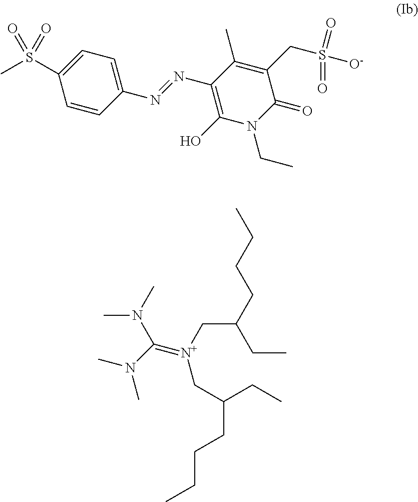 [SMILES: CCn1c(O)c(/N=N/c2ccc(S(C)(=O)=O)cc2)c(C)c(CS(=O)(=O)[O-])c1=O ; CCCCC(CC)C[N+](CC(CC)CCCC)=C(N(C)C)N(C)C]

27.5 g (66 mmol) of the hexaalkylguanidinium chloride (C2a) are dissolved at 90° C. in 500 mL of water while stirring (solution A).

29.2 g (64 mmol) of the yellow acid azo dye of the formula (I a) are introduced into 500 mL of water and, after the addition of five drops of 15% by weight sodium carbonate solution, heated to 60 to 65° C. This suspension is added in portions at about 90° C. to solution A. After one hour of reaction time at this temperature, an emulsion is obtained, which is cooled, and then the water phase is decanted off. The oily organic phase is taken up with 350 mL of methoxypropyl acetate, dried with magnesium sulfate and stored at 4° C. for one night. After the precipitated solid has been filtered off, the solvent is removed under reduced pressure and the resultant residue is dried to constant weight.

The dyes in table 1 were obtained by an analogous procedure.

For the dye anion of example I l, rather than 4-aminophenyl methyl sulfone, an equivalent amount of 4-aminophenyl p-tolyl sulfone is used. For the dye anions of examples I m to I p, rather than 4-aminophenyl methyl sulfone, an equivalent amount of 4-aminophenylsulfonic acid is used.

TABLE 1
(dye salts prepared)

| No.: | Countercation M⁺ | Dye anion |
|---|---|---|
| I a | Na⁺ | 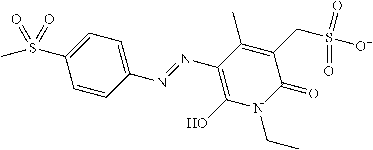 [SMILES: CCn1c(O)c(/N=N/c2ccc(S(C)(=O)=O)cc2)c(C)c(CS(=O)(=O)[O-])c1=O] |
| I b | 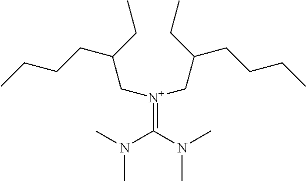 [SMILES: CCCCC(CC)C[N+](CC(CC)CCCC)=C(N(C)C)N(C)C] | 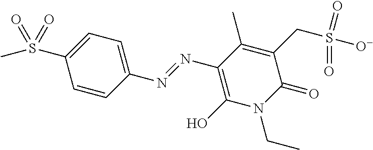 [SMILES: CCn1c(O)c(/N=N/c2ccc(S(C)(=O)=O)cc2)c(C)c(CS(=O)(=O)[O-])c1=O] |
| I c | 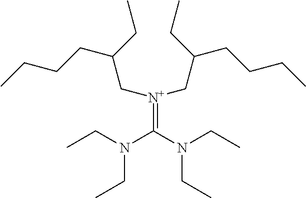 [SMILES: CCCCC(CC)C[N+](CC(CC)CCCC)=C(N(CC)CC)N(CC)CC] | 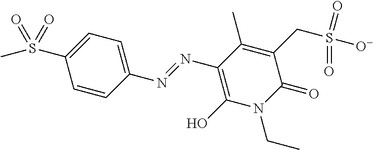 [SMILES: CCn1c(O)c(/N=N/c2ccc(S(C)(=O)=O)cc2)c(C)c(CS(=O)(=O)[O-])c1=O] |
| I d | 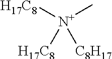 | 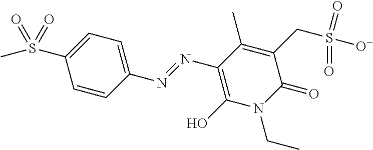 [SMILES: CCn1c(O)c(/N=N/c2ccc(S(C)(=O)=O)cc2)c(C)c(CS(=O)(=O)[O-])c1=O] |
| I e | 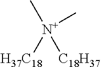 | 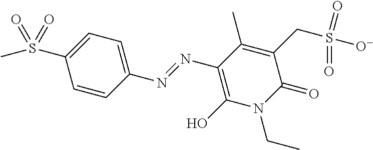 [SMILES: CCn1c(O)c(/N=N/c2ccc(S(C)(=O)=O)cc2)c(C)c(CS(=O)(=O)[O-])c1=O] |
| I f | 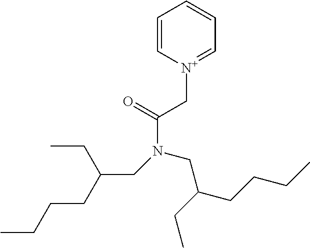 [SMILES: CCCCC(CC)CN(CC(CC)CCCC)C(=O)C[n+]1ccccc1] | 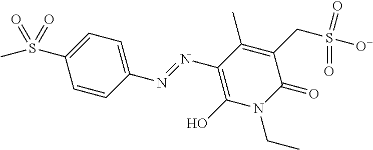 [SMILES: CCn1c(O)c(/N=N/c2ccc(S(C)(=O)=O)cc2)c(C)c(CS(=O)(=O)[O-])c1=O] |
| I g | 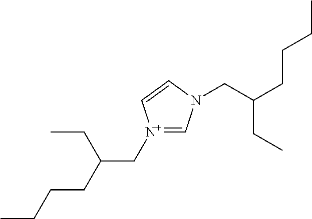 [SMILES: CCCCC(CC)Cn1cc[n+](CC(CC)CCCC)c1] | 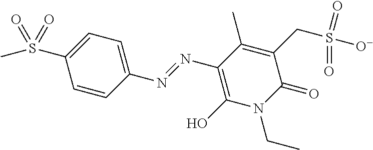 [SMILES: CCn1c(O)c(/N=N/c2ccc(S(C)(=O)=O)cc2)c(C)c(CS(=O)(=O)[O-])c1=O] |
| I h | 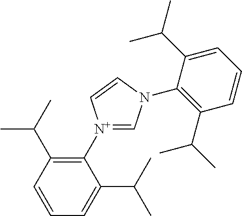 [SMILES: CC(C)c1cccc(C(C)C)c1-n1cc[n+](-c2c(C(C)C)cccc2C(C)C)c1] | 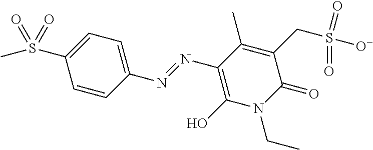 [SMILES: CCn1c(O)c(/N=N/c2ccc(S(C)(=O)=O)cc2)c(C)c(CS(=O)(=O)[O-])c1=O] |
| I i | 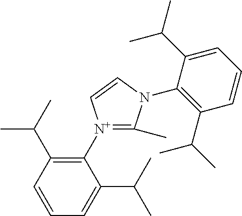 [SMILES: Cc1n(-c2c(C(C)C)cccc2C(C)C)cc[n+]1-c1c(C(C)C)cccc1C(C)C] | 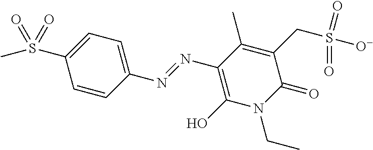 [SMILES: CCn1c(O)c(/N=N/c2ccc(S(C)(=O)=O)cc2)c(C)c(CS(=O)(=O)[O-])c1=O] |
| I j | 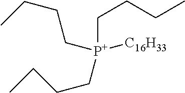 | 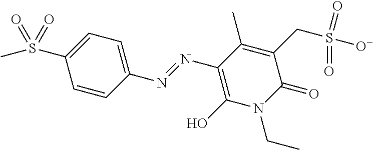 [SMILES: CCn1c(O)c(/N=N/c2ccc(S(C)(=O)=O)cc2)c(C)c(CS(=O)(=O)[O-])c1=O] |
| I k | 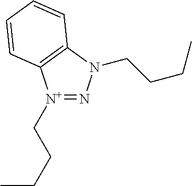 [SMILES: CCCCn1n[n+](CCCC)c2ccccc21] | 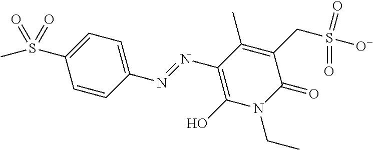 [SMILES: CCn1c(O)c(/N=N/c2ccc(S(C)(=O)=O)cc2)c(C)c(CS(=O)(=O)[O-])c1=O] |
| I l | 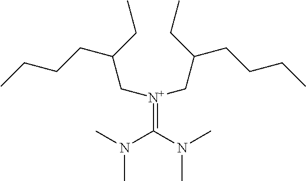 [SMILES: CCCCC(CC)C[N+](CC(CC)CCCC)=C(N(C)C)N(C)C] | 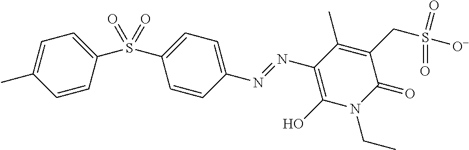 [SMILES: CCn1c(O)c(/N=N/c2ccc(S(=O)(=O)c3ccc(C)cc3)cc2)c(C)c(CS(=O)(=O)[O-])c1=O] |
| I m | 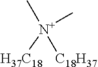 | 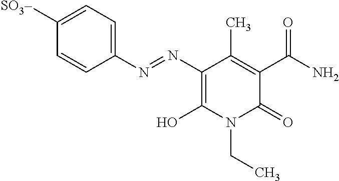 |
| I n | 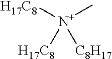 | 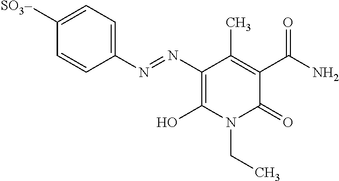 |
| I o | 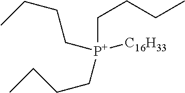 | 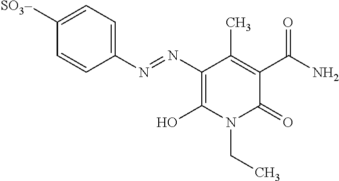 |
| I p | 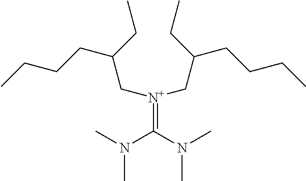 [SMILES: CCCCC(CC)C[N+](CC(CC)CCCC)=C(N(C)C)N(C)C] | 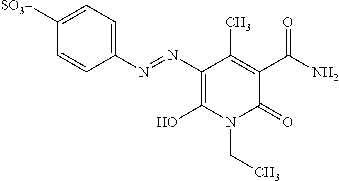 |

Each of these are yellow substances having breakdown points >200° C.

Further dye anions were prepared proceeding from the following nitrilopyridones:

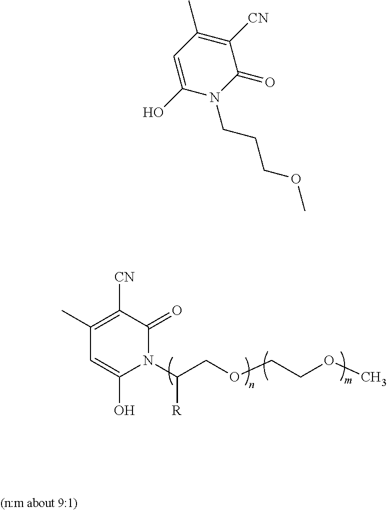

They are obtainable from methyl cyanoacetate, methyl acetoacetate and the corresponding amine—methoxypropylamine or Jeffamine® M600. The nitrile group can be removed by heating with dilute sulfuric acid. The resultant 3,5-unsubstituted pyridones are reacted with formaldehyde and sodium bisulfite by a known procedure (analogously to DE 2162858), giving the following pyridone coupling agents:

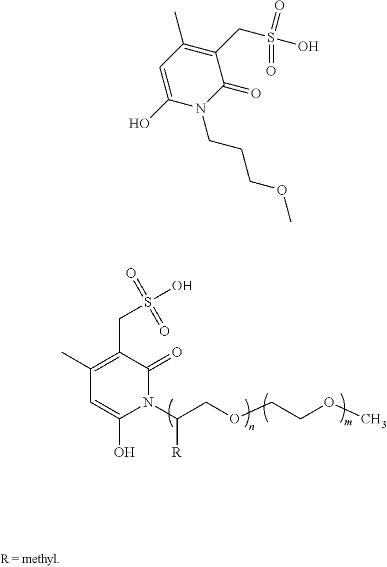

These were used to obtain the dyes I q and I s. The reaction of the Na dye salts mentioned with the respective quaternary ammonium compounds analogously to the preparation of I b gave the dye salts I r and I t therefrom.

| No.: | Countercation M⁺ | Dye anion |
|---|---|---|
| I q | Na⁺ | 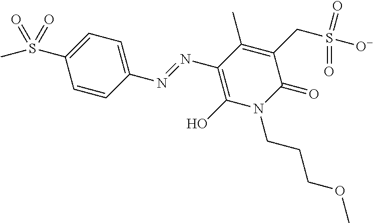 [SMILES: COCCCn1c(O)c(/N=N/c2ccc(S(C)(=O)=O)cc2)c(C)c(CS(=O)(=O)[O-])c1=O] |
| I r | 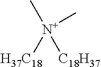 | 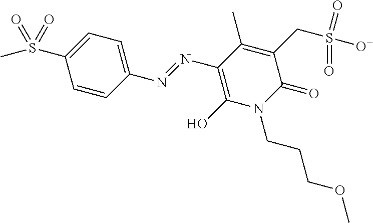 [SMILES: COCCCn1c(O)c(/N=N/c2ccc(S(C)(=O)=O)cc2)c(C)c(CS(=O)(=O)[O-])c1=O] |
| I s | Na⁺ | 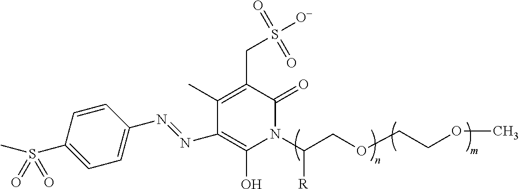 |
| I t | 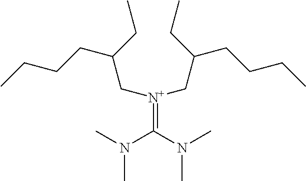 [SMILES: CCCCC(CC)C[N+](CC(CC)CCCC)=C(N(C)C)N(C)C] | 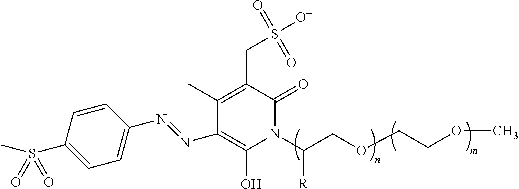 |

Examples of the production of the compositions of the invention, comprising dyes I and organic pigments:

### Example Z1

### Composition Z1

2.0 g of compound (I a) are ground together with 18.0 g of C.I. Pigment Yellow 138 in an IKA laboratory powder mill. After discharge from the mill, 19.4 g of composition Z1 of the invention are obtained in the form of a greenish-yellow powder.

### Examples Z2 to Z6

Analogously to example Z1, in place of compound I a, the dyes listed in table 3 below were used. The compositions Z2 to Z6 of the invention are obtained in each case.

TABLE 3

| Example | Dye | Pigment |
|---|---|---|
| Z1 | I a | C.I. Pigment Yellow 138 |
| Z2 | I d | C.I. Pigment Yellow 138 |
| Z3 | I b | C.I. Pigment Yellow 138 |
| Z4 | I g | C.I. Pigment Yellow 138 |
| Z5 | I l | C.I. Pigment Yellow 138 |
| Z6 | I o | C.I. Pigment Yellow 138 |

### Example Z7

The procedure is as in example Z3, except that C.I. Pigment Green 36 rather than C.I. Pigment Yellow 138 is used, and the composition Z7 of the invention is obtained as a yellowish-green solid.

### Example Z8

The procedure is as in example Z1, except that compound (I n) rather than compound (I a) and C.I. Pigment Green 58 rather than C.I. Pigment Yellow 138 are used, and the composition Z8 of the invention is obtained as a yellowish-green solid.

### Example Z9

The procedure is as in example Z3, except that C.I. Pigment Red 254 rather than C.I. Pigment Yellow 138 is used, and the composition Z9 of the invention is obtained as a red solid.

TABLE 4

| Example | Dye | Pigment |
|---|---|---|
| Z7 | I b | C.I. Pigment Green 36 |
| Z8 | I n | C.I. Pigment Green 58 |
| Z9 | I b | C.I. Pigment Red 254 |

### Use Example 10

10.0 g of the composition according to example Z1 are mixed in a paint shaker cup with 72.5 g of methoxypropyl acetate (PGMEA), 5.0 g of n-butanol and 12.5 g of Disperbyk® 2001 (BYK-Chemie, polymeric dispersing aid solution) while stirring. After adding 250 g of zirconia beads (0.3 mm), dispersion is effected in a Lau dispersing unit (Dispermat) for three hours. The resultant millbase is separated from the beads by filtration. The viscosity of the millbase is measured (Haake RheoStress 1 rotary viscometer, cone-plate measurement geometry, 23° C., linear rise in shear rate D to 250 1/s, value determined at 250 1/s).

20.0 g of the resultant millbase are mixed with 20.5 g of a 10% by weight solution of Joncryl® 611 (styrene-acrylate resin, BASF AG) in PGMEA by shaking without beads for 10 minutes. Then the dispersion is filtered.

The resultant binder-containing colorant dispersion is applied with the aid of a spin-coater (POLOS Wafer Spinner) to glass plates (SCHOTT, laser-cut, 10×10 cm), in a layer thickness which enables setting, in the case of use of a C light source, of the color coordinates y specified in Table 5a or the color coordinates x specified in Table 5b as reference values.

The layer thickness in each case is about 1 to 2 micrometers.

The glass plates are left to flash off and then dried at 80° C. in an air circulation drying cabinet (from Binder) for 10 min. The so-called prebake values of the color coordinates (x, y, Y, and CIELAB, Spectrophotometer Datacolor 650, illuminant C, 2° observer), transmission curves (ditto) and contrast values (Tsubosaka CT-1 Contrast Tester) of the glass plates were analyzed. The glass plates are subsequently subjected to a heat treatment in an air circulation drying cabinet at 230° C. for 1 h and analyzed again, from which the postbake values are obtained.

### Comparative Examples: C1-C4

The millbases and color dispersions are produced analogously to the case of use example 10. However, no pigment compositions of the invention are used, but rather the underlying base pigments.

Tables 5a and 5b show the results of the inventive examples and the comparative examples in the postbake.

The relative contrast ratio CR is based on the color dispersion of the respective comparative example (100%).

The values x, y and Y refer to the measured color coordinates in the CIE-Yxy standard color space, where Y is a measure of brightness.

Each inventive composition was compared with the corresponding base pigment. For the contrast value, the contrast value for each base pigment from the comparative example was set to 100%. For the comparison of the brightnesses Y, the difference Yₑₓₐₘₚₗₑ−Y_{comparative example} was formed in each case. If this value is >0, the brightness of the sample of the invention is greater than that of the comparative example.

For the comparison of the viscosities, the viscosity for each comparative example was set to 100%.

TABLE 5a
(Reference to y values).

| | | Relative | | | | |
|---|---|---|---|---|---|---|
| | | viscosity of | | | | |
| | | the millbase | y | | Relative | CR |
| Example | Description | [%] | (ref.) = | x = | Y value | [%] |
| 10 | Z1 | 83 | 0.500 | 0.428 | +2.7 | 185 |
| 11 | Z2 | 83 | 0.500 | 0.428 | +2.7 | 185 |
| 12 | Z3 | 40 | 0.500 | 0.429 | +4.5 | 253 |
| 13 | Z4 | 53 | 0.500 | 0.430 | +3.1 | 177 |
| 14 | Z5 | 38 | 0.500 | 0.427 | +4.6 | 267 |
| 15 | Z6 | 95 | 0.500 | 0.431 | +1.3 | 117 |
| C1 | C.I. Pigment | 100 | 0.500 | 0.435 | 0 (ref.) | 100 |
| | Yellow 138 | | | | | |
| 16 | Z7 | 20 | 0.420 | 0.255 | +0.9 | 103 |
| C2 | C.I. Pigment | 100 | 0.420 | 0.248 | 0 (ref.) | 100 |
| | Green 36 | | | | | |
| 17 | Z8 | 85 | 0.500 | 0.283 | +2.0 | 107 |
| C3 | C.I. Pigment | 100 | 0.500 | 0.260 | 0 (Ref.) | 100 |
| | Green 58 | | | | | |

TABLE 5b
(Reference to x values).

| | | Relative | | | | |
|---|---|---|---|---|---|---|
| | | viscosity of | | | | |
| Use | | the millbase | | | Relative | CR |
| example | Description | [%] | y = | x = (ref.) | Y value | [%] |
| 18 | Z9 | 8 | 0.317 | 0.620 | +0.5 | 126 |
| C4 | C.I. Pigment | 100 | 0.314 | 0.620 | 0 | 100 |
| | Red 254 | | | | | |

The millbases of the compositions of the invention have reduced viscosities compared to those of the untreated pigments. The inventive examples, in the color filter application, show increased brightness Y and an improved contrast value. They have steeper transmission curves.

Example of the production of a micronized colorant composition by addition during a salt kneading operation:

### Example K1

In a laboratory kneader (Werner & Pfleiderer, 300 mL), 2.0 g of compound (I b) are kneaded with 18.0 g of commercial C.I. Pigment Yellow 138 with addition of 120 g of sodium chloride and 25 mL of diethylene glycol at a temperature of 80° C. for 18 h. The kneaded dough is stirred in 0.9 L of water for two hours and the composition is then filtered. The filtercake is treated again by stirring with 0.9 L of demineralized water for 1 h. After filtration, the colorant composition is washed with water and dried under reduced pressure.

This gives a greenish-yellow pigment composition K1 in a fine state of subdivision.

### Comparative Example KC1

A salt kneading operation in which 20.0 g of commercial C.I. Pigment Yellow 138 are kneaded with 120 g of sodium chloride and 25 mL of diethylene glycol at a temperature of 80° C. for 18 h is conducted. The kneaded dough is stirred in 0.9 L of water for two hours and the composition is then filtered. The filtercake is treated again by stirring with 0.9 L of demineralized water for 1 h. After filtration, the colorant composition is washed with water and dried under reduced pressure.

### Example K2

The procedure is as in example K1, except that dye (I d) rather than (I b) is used, and the micronized colorant composition K2 is obtained (greenish yellow).

### Example K3

The procedure is as in example K1, except that dye (I r) rather than (I b) is used, and the micronized composition K3 is obtained (greenish yellow).

### Application Testing of Examples K1-3 and KC1

The micronized compositions are tested in analogy to use example 10. However, in place of composition Z1, the compositions specified in table 6 below are used.

TABLE 6
(Reference to y values).

| | | | | | Relative |
|---|---|---|---|---|---|
| | | | | | contrast |
| | | | x = | Relative | value |
| Example | Description | y = | (ref.) | Y value | [%] |
| K1 | micronized composition K1 | 0.500 | 0.425 | +4.2 | 280 |
| K2 | micronized composition K2 | 0.500 | 0.423 | +3.2 | 167 |
| K3 | micronized composition K3 | 0.500 | 0.422 | +3.7 | 190 |
| KV1 | micronized C.I. Pigment | 0.500 | 0.432 | 0 | 100 |
| | Yellow 138 | | | | |

The micronized compositions K1-K3 of the invention have a higher contrast value and higher brightness Y than each analogous salt-kneaded pure pigment.

1. A colorant composition comprising at least one compound of the formula (I) and at least one pigment, wherein the at least one compound of the formula (I) has the following formula: 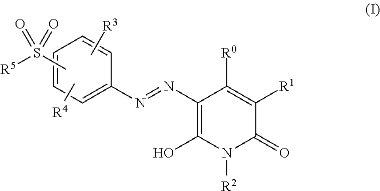
R⁰ is C₁-C₆-alkyl or CF₃;
R¹ is sulfo, carboxyl, C₁-C₄-alkylenesulfo, C₁-C₄-alkylenecarboxy, CONH₂, CONH(C₁-C₄-alkyl) or CN,
R² is C₁-C₁₈-alkyl, C₂-C₁₈-alkenyl, hydroxy-C₁-C₁₈-alkyl, or —(C₁-C₆-alkylene-O—)ₘ—R, wherein R is H, C₁-C₁₆-alkyl or hydroxy-C₁-C₁₆-alkyl and m is a number from 1 to 20,
R³ is H, sulfo, carboxyl, C₁-C₆-alkyl or C₁-C₆-alkoxy,
R⁴ is H, C₁-C₆-alkyl or C₁-C₆-alkoxy,
R⁵ is OH, OM, C₁-C₆-alkyl, unsubstituted C₆-C₁₀-aryl or C₁-C₆-alkyl-, halogen-, carboxyl- or sulfo-substituted C₆-C₁₀-aryl,
wherein the at least one compound of the formula (I) contains at least one anionic radical from the group of sulfo and carboxyl having the countercation M⁺, wherein M⁺ is an alkali metal cation or an organic cation.

2. The colorant composition as claimed in claim 1, wherein the at least one compound of the formula (I) contains at least one sulfo group having the countercation M⁺.

3. The colorant composition as claimed in claim 1, wherein the countercation M⁺ is an organic ammonium cation or an organic phosphonium cation.

4. The colorant composition as claimed in claim 3, wherein the organic ammonium cation is a primary, secondary, tertiary or quaternary ammonium cation.

5. The colorant composition as claimed in claim 3, wherein the organic ammonium cation is an imidazolium cation, alkylguanidinium cation, benzotriazolyl cation or pyridinium cation.

6. The colorant composition as claimed in claim 1, wherein the at least one pigment is an organic pigment.

7. The colorant composition as claimed in claim 1, wherein the at least one organic pigment is selected from the group consisting of anthraquinone pigments, laked or unlaked azo pigments, anthanthrone pigments, benzimidazolone pigments, quinacridone pigments, quinophthalone pigments, diketopyrrolopyrrole pigments, dioxazine pigments, disazo condensation pigments, isoindolinone pigments, isoindoline pigments, metal complex pigments, perinone pigments, perylene pigments, phthalocyanine pigments and triarylcarbonium pigments.

8. The colorant composition as claimed in claim 1, wherein the mixing ratio of the at least one compound of the formula (I) to the at least one pigment is from 1:99 to 99:1 parts by weight.

9. The colorant composition as claimed in claim 1, wherein the at least one compound of the formula (I) is present in an amount of 1% to 20% by weight, based on the total weight of the colorant composition.

10. A millbase comprising 0.01% to 45% by weight of a colorant composition as claimed in claim 1, dispersed in at least one organic solvent.

11. A binder-containing colorant dispersion comprising 0.01% to 40% by weight of a colorant composition as claimed in claim 1, dispersed in at least one organic solvent, at least one polymeric binder and, optionally, further auxiliaries.

12. A process for producing a colorant composition as claimed in claim 1, comprising the step of combining the at least one compound of the formula (I) and the at least one pigment with one another.

13. A high molecular weight organic material of natural or synthetic origin comprising at least one colorant composition as claimed in claim 1.

14. A colored color filter, a colored crystal colored OLED display or a colored bulk polymer comprising a high molecular weight organic material of natural or synthetic origin as claimed in claim 13.
